(19) United States
(12) Patent Application Publication
(10) Pub. No.: US 2010/0034401 A1
(43) Pub. Date: Feb. 11, 2010

(54) AUDIO PLAYER WITH ILLUMINATION EFFECT

(76) Inventor: Ching-Shan Huang, Sijhih City (TW)

Correspondence Address: Hershkovitz & Associates, LLC, 2845 Duke Street, Alexandria, VA, 22314, US

(21) Appl. No.: 12/186,170

(22) Filed: Aug. 5, 2008

(51) Int. Cl. H03F 21/00

(52) U.S. Cl. 381/120

(57) ABSTRACT

An audio player with illumination effect has an audio play host and a lighting box. The audio play host has a housing in which speakers, a circuit board and a power amplifiers are mounted. The housing further has audio signal connectors, buttons and a display and is defined with at least one mounting hole. The lighting box is mounted on the audio play host and has a casing, at least one lamp socket and at least one lamp. The lamp socket with two ends respectively extends into the housing and the casing to electrically connect the circuit board and hold the lamp. In addition to amplify and output an audio signal from the audio signal connectors, the control circuit determines on and off operations and illuminating intensity of the lighting box.

### BACKGROUND OF THE INVENTION

1. Field of the Invention

The present invention relates to an audio player, and more particularly to an audio player with illumination effect.

2. Description of Related Art

Audio-video display devices for either multi-users or single users are very common and widespread in the office or home. The household audio-video display devices may be equipped with high-power speakers to provide better sound effects. However, when the display device is equipped with other facilities, the display device as a whole has a relative large size. Further, if the audio playing device together with household furnishings are arranged in the house, the limited space may be too crowded.

To overcome the shortcomings that the touch panel cannot correctly recognize more than one contact point, the present invention provides a multi-contact points sensible touch panel and a method for controlling the same to mitigate or obviate the aforementioned problems.

### SUMMARY OF THE INVENTION

An objective of the present invention is to provide an audio player with illumination effect, wherein the audio player is integrated with sound-playing and illuminating abilities.

An audio player with illumination effect has an audio play host and a lighting box. The audio play host has a housing in which speakers, a circuit board and a power amplifiers are mounted. The housing further has audio signal connectors, buttons and a display and is defined with at least one mounting hole. The lighting box is mounted on the audio play host and has a casing, at least one lamp socket and at least one lamp. The lamp socket with two ends respectively extend into the housing and the casing to electrically connect the circuit board and hold the lamp. In addition to amplify and output an audio signal that is received from the audio signal connectors, the control circuit determines on and off operations and illuminating intensity of the lighting box.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of an audio player with illumination effect in accordance with the present invention;

FIG. 2 is an exploded perspective view of the audio player of FIG. 1;

FIG. 3 is a side view of the audio player of FIG. 1;

FIG. 4 is a circuit block diagram of the audio player of FIG. 1; and

FIG. 5 is an operational view of the audio player being connected to a computer in accordance with the present invention; and

FIG. 6 is another operational view of the audio player communicating with a computer wirelessly in accordance with the present invention.

### DETAILED DESCRIPTION OF THE PREFERRED EMBODIMENT

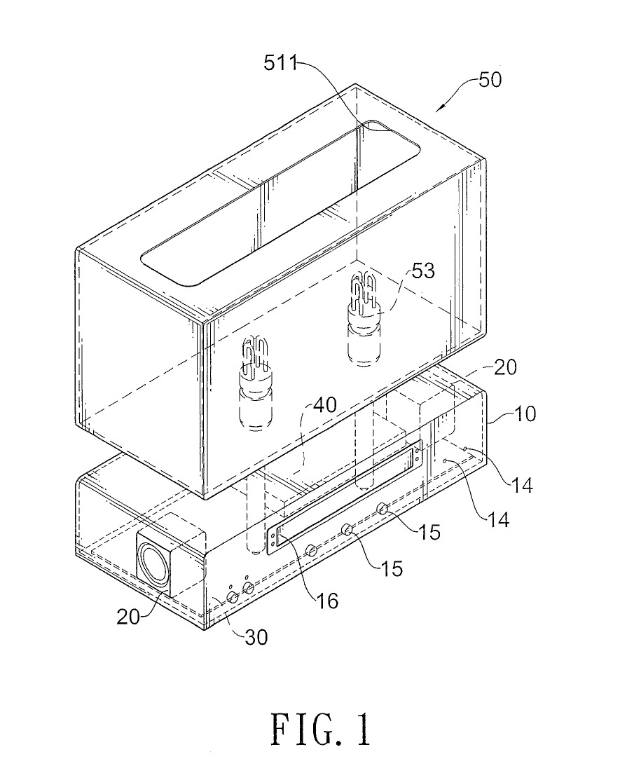

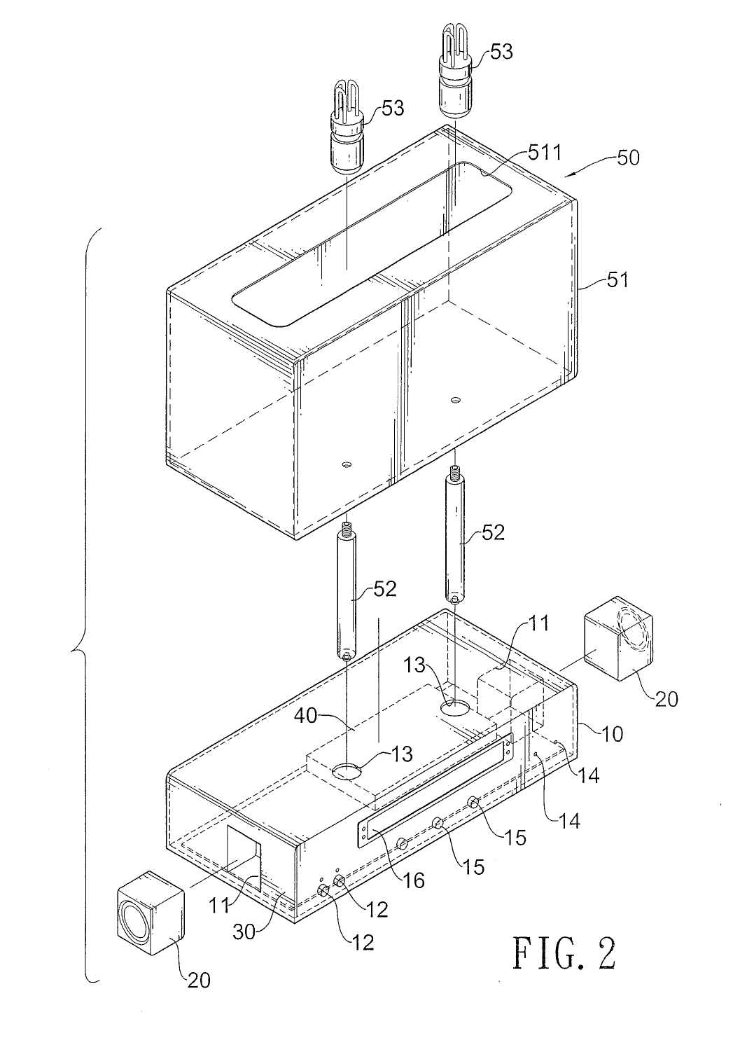

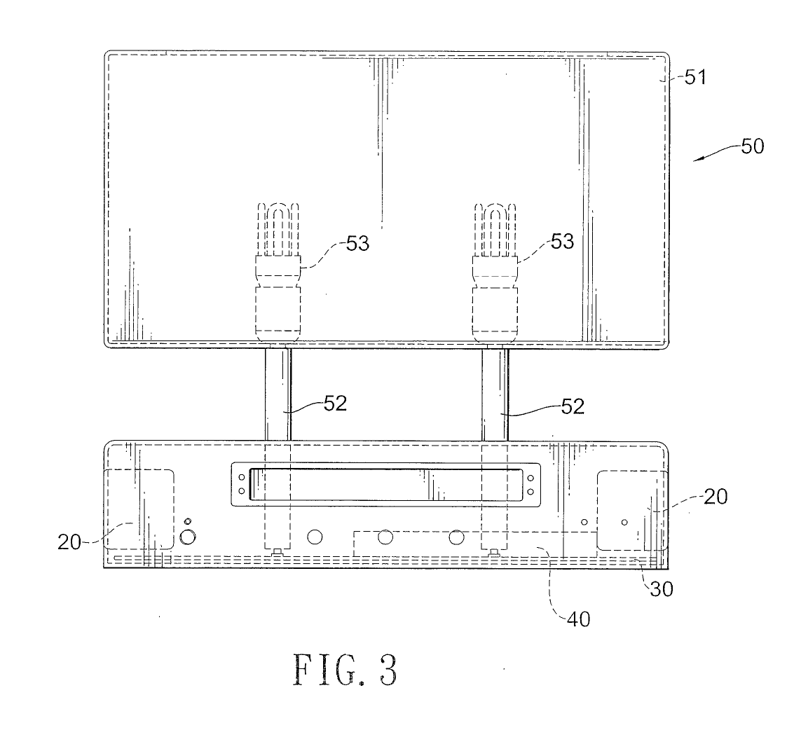

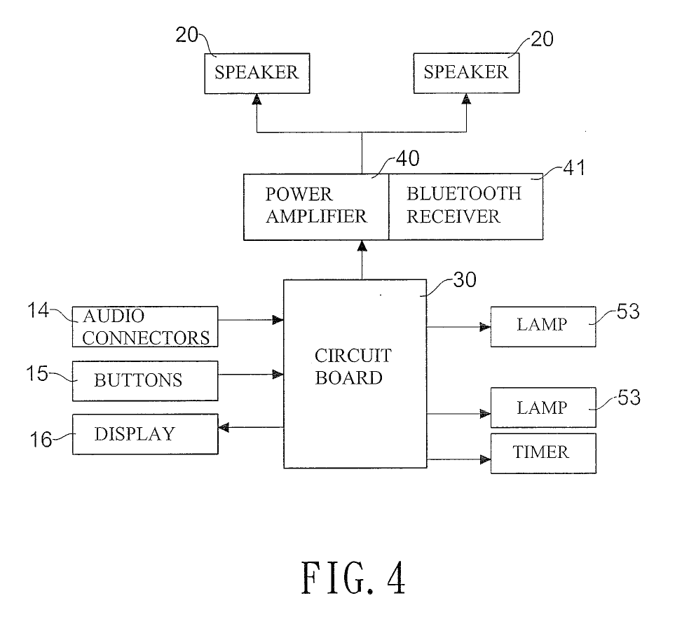

With reference to FIGS. 1 to 4, an audio player with illumination effect in accordance with the present invention comprises an audio playing host and a lighting box (50). The audio playing host comprises a housing (10), two speakers (20), a circuit board (30) and a power amplifier (40).

The housing (10) has a top surface, two opposite side surfaces, a front surface, two openings (11), multiple through holes (12), at least one mounting hole (13), audio signal connectors (14), buttons (15) and a display (16). The two openings (11) are respectively defined through the opposite side surfaces of the housing (10). The through holes (12) are defined through the front surface of the housing (10). The at least one mounting hole (13) is defined through the top surface of the housing (10). In this embodiment, two mounting holes (13) are provided on the housing (10). The audio signal connectors (14) may be audio sockets, jacks, plugs or the like and are mounted in the through holes (12). The buttons (15) may be rotatable tuners and are mounted in the through holes (12) and protrude from the front surface. The display (16) may be a liquid crystal display (LCD) and is mounted in the through hole (12).

The two speakers (20) are mounted in the housing (10) and respectively correspond to the two openings (11).

The circuit board (30) is securely mounted in the housing (10), electrically connects to the audio signal connectors (14), the buttons (15) and the display (16), and outputs an audio signal.

The power amplifier (40) is securely mounted in the housing (10) and electrically connects between the circuit board (30) and the two speakers (20). The power amplifier (40) amplifies the audio signal output from the circuit board (30) and then transmits the amplified audio signal to the speakers (20). The power amplifier (40) may further comprise a bluetooth receiver (40) to receive a wireless audio signal to be amplified. Thus, the audio playing host can receive the audio signal from an external multimedia source such as a computer, a MP3 player, a cell phone, a notebook computer or the like.

The lighting box (10) is mounted on the audio playing host and comprises a casing (51), at least one lamp socket (52) and at least one lamp (53). The casing (51) has a bottom, a top and an operation opening (511) defined through the top. The at least one lamp socket (52) has a bottom end protruding through the mounting hole (13) and electrically connected with the circuit board (13), and has a top end extending into the bottom of the casing (51) for electrically holding the lamp (53). The lamp (53) can be placed in the casing (51) through the operation opening (511) and mounted on the lamp socket (52). The on/off status and light intensity of the lamp (53) is controllable under the operations of the buttons (15).

The circuit board (30) may further comprise a timer to provide a time display function and an alarm clock function. Thus the display (16) can show a real time. The circuit board (30) may also control the display (16) to show related information of the audio signals being played.

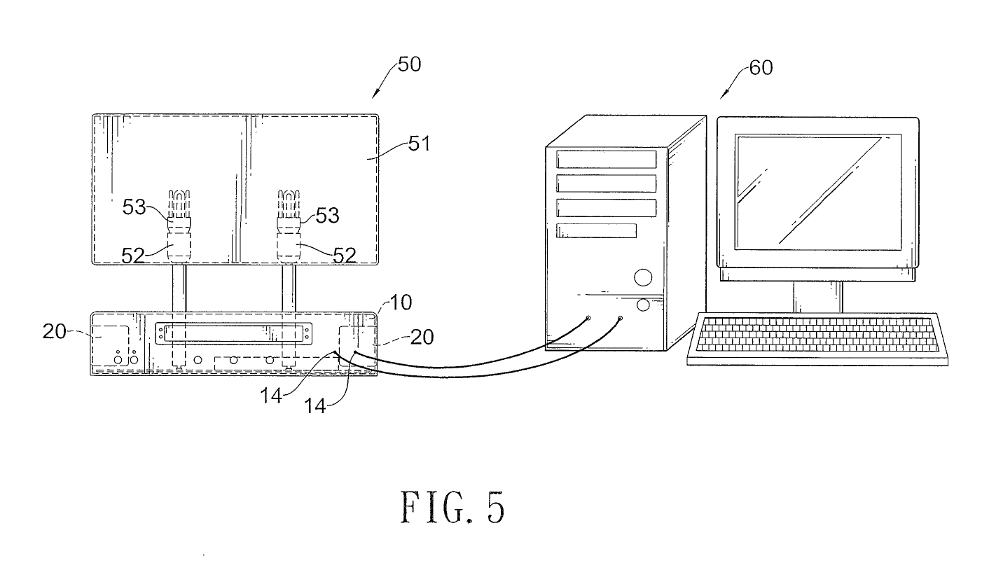

With reference to FIG. 5, when the audio player with the audio signal connectors (14) links to a computer (60) via the audio signal wires, the circuit board (30) receives the audio signal from the computer (60) and transmits the audio signal to the power amplifier (40). After the audio signal is amplified by the power amplifier (40), the speakers (20) converts the amplified audio signal to sound.

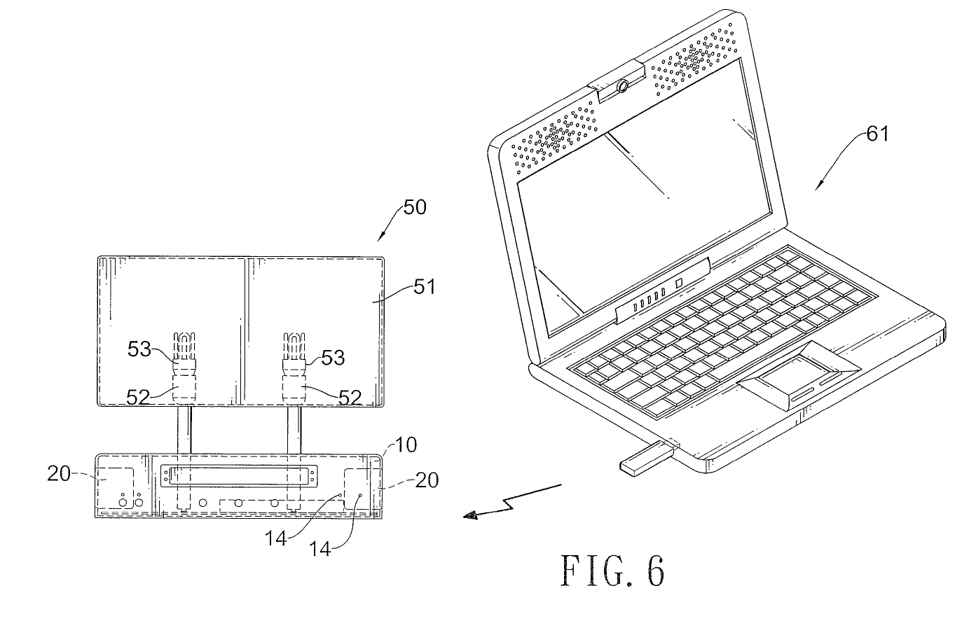

With further reference to FIG. 6, the audio player wirelessly links to a notebook computer (61) through bluetooth protocol. The audio signal is output from a bluetooth module in the notebook computer (61) and received by the bluetooth receivers (41). The received audio signal is amplified by the power amplifier (40) and transmitted to the speakers (20) for play. In short, the audio player in accordance with the present invention receives the audio signals through either wired or wireless transmission, and accommodates more kinds of the audio sources.

Since the lighting box is supported on the audio play host, and the lamps in the lighting box are electrically mounted on the lamp sockets that connect to the circuit board in the housing, the audio player in accordance with the present invention can provide both illumination and sound effects. The lighting box can be used as an illumination light in dark environment or a decoration light. Further, because the lighting box and the audio play host are connected by the lamp sockets, assembling process is simple. With the operation opening defined on the casing of the lighting box, users may easily renew the lamps.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An audio player with illumination effect comprising:
a housing having a top surface, two opposite side surfaces, a front surface and comprising
two openings respectively defined through the two opposite side surfaces;
multiple through holes defined through the front surface;
at least one mounting hole defined through the top surface; and
audio signal connectors, buttons and a display respectively mounted in the through holes;
two speakers mounted in the housing and respectively corresponding two openings of the housing;
a circuit board securely mounted in the housing, electrically connecting to the audio signal connectors, the buttons and the display, outputting an audio signal and comprising a timer for showing a time on the display;
a power amplifier mounted in the housing and electrically connecting between the circuit board and the two speakers, amplifying the audio signal output from the circuit board and then transmitting the audio signal to the speakers;
a lighting box comprising
a casing having a top and a bottom;
at least one lamp socket having a bottom end protruding through the at least one mounting hole and electrically connected to the circuit board, and having a top end extending into the bottom of the casing; and
at least one lamp electrically mounted on the top end of the at least one lamp socket, and being controlled by the circuit board.

2. The audio player as claimed in claim 1, wherein the lighting box comprises
two lamp sockets;
two lamps respectively mounted on the two lamp sockets; and
an operation opening defined through the top of the casing.

3. The audio player as claimed in claim 1, wherein the buttons comprise rotatable tuners and the display is a liquid crystal display.

4. The audio player as claimed in claim 2, wherein the buttons comprise rotatable tuners and the display is a liquid crystal display.

5. The audio player as claimed in claim 1, wherein the power amplifier further comprises a bluetooth receiver for receiving a wireless audio signal to be amplified.

6. The audio player as claimed in claim 2, wherein the power amplifier further comprises a bluetooth receiver for receiving a wireless audio signal to be amplified.

7. The audio player as claimed in claim 3, wherein the power amplifier further comprises a bluetooth receiver for receiving a wireless audio signal to be amplified.

8. The audio player as claimed in claim 4, wherein the power amplifier further comprises a bluetooth receiver for receiving a wireless audio signal to be amplified.
